(19) United States
(12) Patent Application Publication
(10) Pub. No.: US 2020/0300782 A1
(43) Pub. Date: Sep. 24, 2020

(54) ELECTRONIC COMPONENT HANDLER AND ELECTRONIC COMPONENT TESTER

(71) Applicant: Seiko Epson Corporation, Tokyo (JP)

(72) Inventor: Noriaki KOTANI, Hara (JP)

(21) Appl. No.: 16/822,097

(22) Filed: Mar. 18, 2020

(30) Foreign Application Priority Data
Mar. 19, 2019 (JP) 2019-050766

(51) Int. Cl. G01N 21/956; G01R 31/308; G01R 31/28

(52) U.S. Cl. CPC G01N 21/95607; G01R 31/2893; G01R 31/308

(57) ABSTRACT

A handler that transports an electronic component (IC device) to a test unit includes a holding member (shuttle plate) including a recess having a colored bottom portion and housing the electronic component in the recess, an imaging unit (imaging device) that images the recess, and a control unit that compares a reference area of the bottom portion previously calculated from a plan view area of the electronic component and a plan view area of the bottom portion with a detection area of the bottom portion detected from an image captured by the imaging unit, and determines presence or absence of the electronic component housed in the recess or whether or not a position of the electronic component housed in the recess is good.

The present application is based on, and claims priority from JP Application Serial Number 2019-050766, filed Mar. 19, 2019, the disclosure of which is hereby incorporated by reference herein in its entirety.

### BACKGROUND

### 1. Technical Field

The present disclosure relates to an electronic component handler and electronic component tester.

### 2. Related Art

In related art, electronic component testers also called handers that transport electronic components to test units and test characteristics etc. of the electronic components are used. For example, International Publication 06/109358 discloses an electronic component tester that stores reference image data of a socket without an electronic component to be tested attached thereto acquired from a captured image captured in advance, and determines whether or not the electronic component to be tested remains in the socket by comparison between test image data of the imaged socket and the stored reference image data of the socket.

However, in the electronic component tester disclosed in International Publication 06/109358, a method such as image matching is used for the comparison between the test image data of the imaged socket and the stored reference image data of the socket and it is necessary to recognize a shape in the captured image and compare between a recognized shape image and a reference image, and there is a problem that a longer time is taken for a determination.

### SUMMARY

An electronic component handler according to an application is an electronic component handler that transports an electronic component to a test unit, including a holding member including a recess having a colored bottom portion and housing the electronic component in the recess, an imaging unit that images the recess, and a control unit that compares a reference area of the bottom portion previously calculated from a plan view area of the electronic component and a plan view area of the bottom portion with a detection area of the bottom portion detected from an image captured by the imaging unit, and determines presence or absence of the electronic component housed in the recess or whether or not a position of the electronic component housed in the recess is good.

In the above described electronic component handler, a color coloring the bottom portion may be different from a color of the electronic component.

In the above described electronic component handler, a color coloring the bottom portion may be different from a color of the holding member.

In the above described electronic component handler, the imaging unit may be placed above the recess.

In the above described electronic component handler, the control unit may acquire the plan view area of the electronic component and the plan view area of the bottom portion from an image previously captured by the imaging unit.

In the above described electronic component handler, a plurality of the recesses may be provided, the imaging unit may previously image with respect to each of the recesses, and the control unit may acquire the plan view area of the electronic component and the plan view area of the bottom portion in correspondence with the captured images of the respective recesses.

In the above described electronic component handler, the image previously captured by the imaging unit may include an image of the bottom portion in which the electronic component is not housed and an image of the bottom portion in which the electronic component is housed.

In the above described electronic component handler, the holding member may include an inclined surface connecting to the bottom portion, and the inclined surface may be colored in a different color from that of the bottom portion.

In the above described electronic component handler, a reporting unit is provided, wherein the control unit may transmit a signal to the reporting unit when determining that the electronic component is not housed in the recess or when determining that a position of the electronic component housed in the recess is skewed, and the reporting unit may receive the signal and report.

In the above described electronic component handler, the control unit may stop the transport when determining that the electronic component is not housed in the recess or when determining that a position of the electronic component housed in the recess is skewed.

An electronic component handler according to an application is an electronic component handler that transports an electronic component to a test unit, including a holding member including a recess having a colored bottom portion and housing the electronic component in the recess, an imaging unit that images the recess, and a control unit that compares a reference ratio of the bottom portion previously calculated from a plan view area of the electronic component and a plan view area of the bottom portion with a detection ratio of the bottom portion detected from an image captured by the imaging unit, and determines presence or absence of the electronic component housed in the recess or whether or not a position of the electronic component housed in the recess is good.

An electronic component tester according to an application includes one of the above described electronic component handlers and a test unit that tests the electronic component transported by the electronic component handler.

### BRIEF DESCRIPTION OF THE DRAWINGS

FIG. 1 is a perspective view showing a schematic configuration of an electronic component tester including an electronic component handler according to an embodiment.

FIG. 2 is a plan view showing a schematic configuration of the electronic component tester including the electronic component handler.

FIG. 3 is a sectional view showing a schematic configuration of an imaging unit.

FIG. 4 is a plan view showing a schematic configuration of a shuttle plate as an example of a holding member.

FIG. 5 is a sectional view along A-A in FIG. 4 showing the schematic configuration of the shuttle plate.

FIG. 6 is a block diagram showing a schematic configuration of the electronic component tester.

FIG. 7 is a flowchart showing a checking method of an IC device as an electronic component housed in a recess.

FIG. 8 is an enlarged plan view showing the recess of the shuttle plate.

FIG. 9 is an enlarged plan view showing the recess of the shuttle plate with the IC device housed therein.

FIG. 10 is an enlarged sectional view showing the recess of the shuttle plate with the IC device housed therein.

FIG. 11 is a plan view showing a case where a housing location of the IC device is displaced.

FIG. 12 is an explanatory chart relating to a determination of a position or presence or absence of the IC device.

FIG. 13 is a sectional view showing a configuration example in which inclined surfaces of the recess are colored.

### DESCRIPTION OF EXEMPLARY EMBODIMENTS

As below, an electronic component handler and electronic component tester according to the present disclosure will be explained in detail based on embodiments shown in the accompanying drawings. Note that the embodiments to be explained do not unduly limit the present disclosure described in the appended claims. Further, not all of the configurations explained in the embodiments are necessarily the essential component elements of the present disclosure.

### 1. Configurations of Electronic Component Handler and Electronic Component Tester

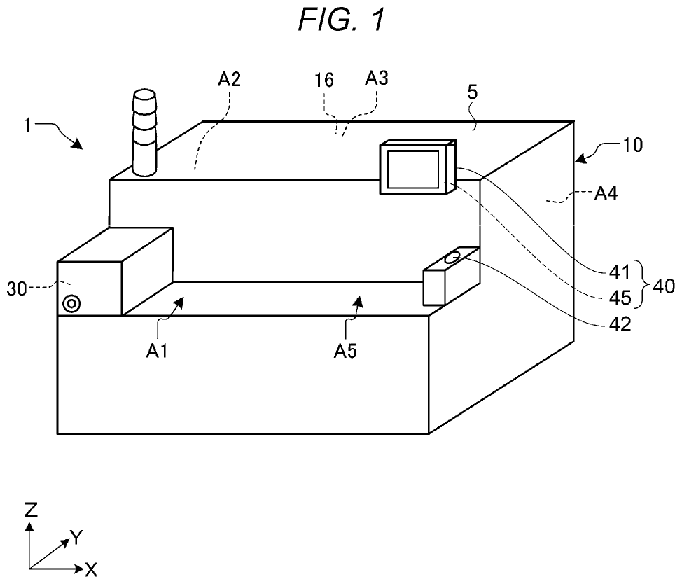

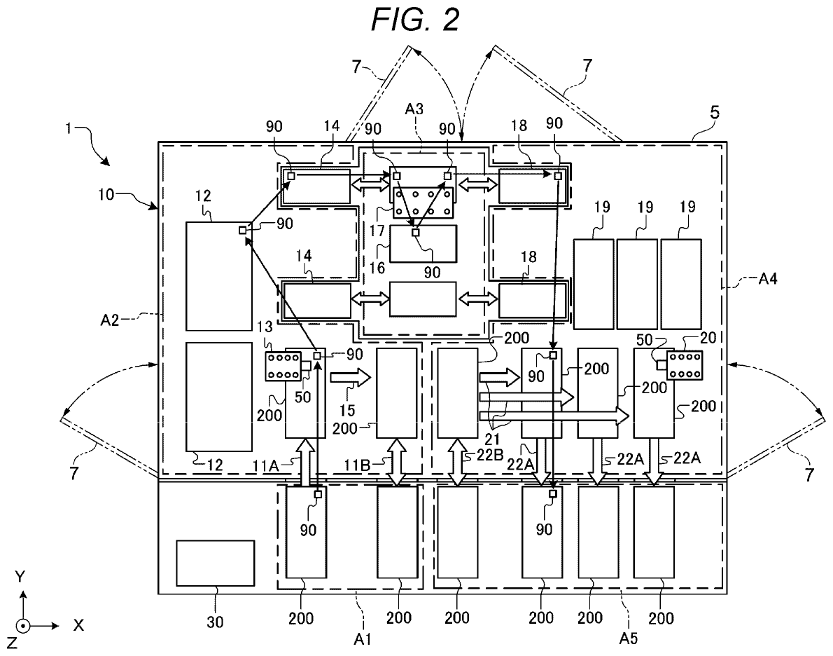

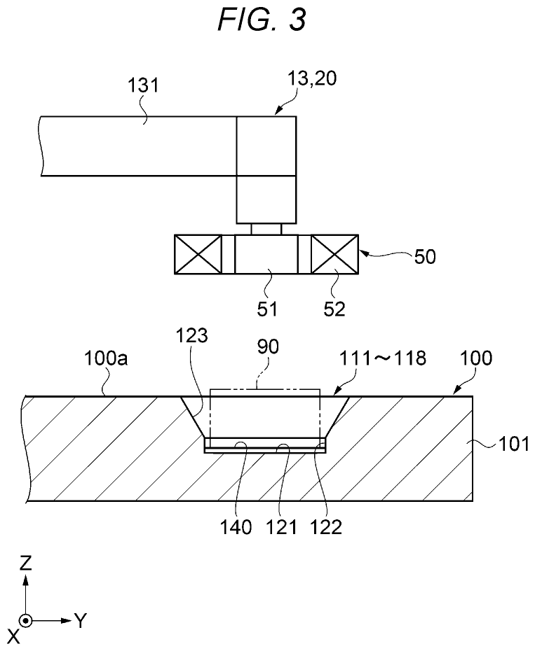

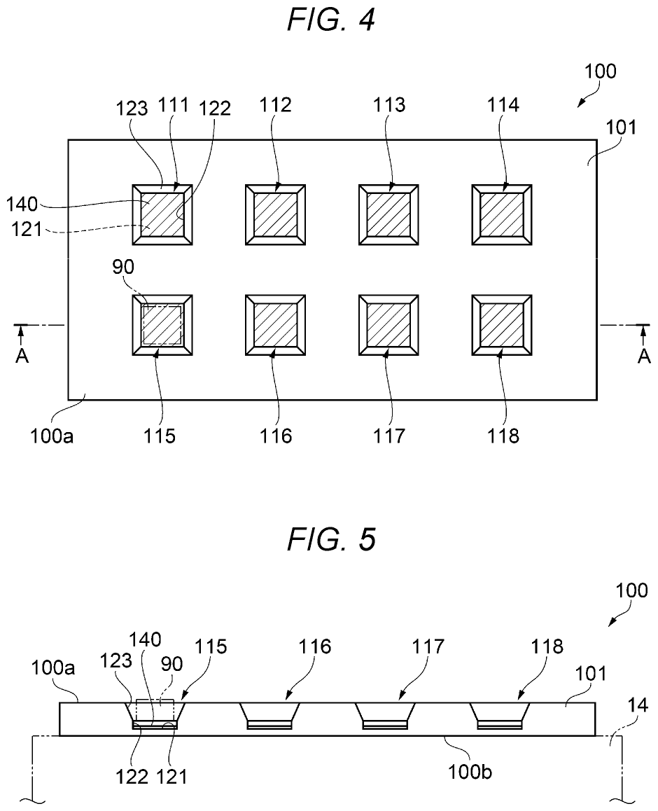

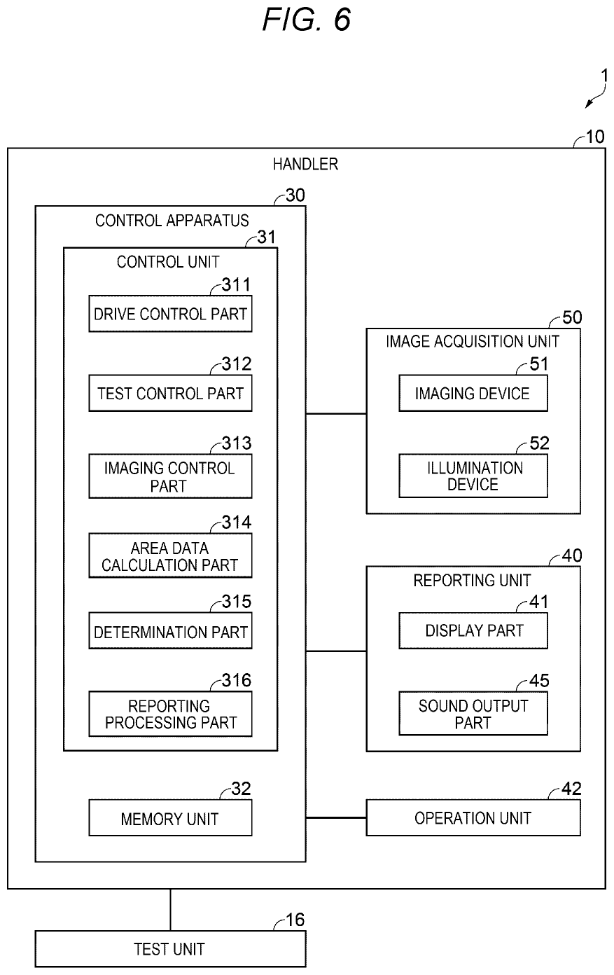

First, referring to FIGS. 1, 2, 3, 4, 5, and 6, the electronic component handler and electronic component tester using the electronic component handler according to an embodiment of the present disclosure will be explained. FIG. 1 is the perspective view showing the schematic configuration of the electronic component tester including the electronic component handler according to the embodiment. FIG. 2 is the plan view showing the schematic configuration of the electronic component tester including the electronic component handler. FIG. 3 is the sectional view showing the schematic configuration of the imaging unit. FIG. 4 is the plan view showing the schematic configuration of the shuttle plate as the example of the holding member. FIG. 5 is the sectional view along A-A in FIG. 4 showing the schematic configuration of the shuttle plate. FIG. 6 is the block diagram showing the schematic configuration of the electronic component tester.

Note that, in FIGS. 1, 2, and 3, for convenience of explanation, an X-axis, a Y-axis, and a Z-axis as three axes orthogonal to one another are shown by arrows, and the pointer sides of the arrows are referred to as “+ (plus)” and the tail sides are referred to as “− (minus)”. Further, hereinafter, directions parallel to the X-axis are referred to as “X directions”, directions parallel to the Y-axis are referred to as “Y directions”, and directions parallel to the Z-axis are referred to as “Z directions”. Furthermore, hereinafter, for convenience of explanation, the +Z direction side as the upside in FIG. 1 is referred to as “upper” or “above” and the −Z direction side as the downside is referred to as “lower” or “below”.

An XY plane containing the X-axis and the Y-axis is horizontal and the Z-axis is vertical. Further, the upstream side in a transport direction of an electronic component may be simply referred to as “upstream” and the downstream side may be simply referred to as “downstream”. Furthermore, “horizontal” in this specification is not limited to complete horizontal, but includes slight inclinations (e.g. less than ±5°) relative to horizontal unless transport of the electronic component is hindered.

A tester 1 as the electronic component tester shown in FIGS. 1 and 2 is an apparatus that makes a test and an examination (hereinafter, simply referred to as “test”) of electrical characteristics of an electronic component such as an IC (Integrated Circuit) device e.g. a BGA (Ball Grid Array) package and LGA (Land grid array) package, an LCD (Liquid Crystal Display), and a CIS (CMOS Image Sensor). Note that, as below, for convenience of explanation, a case where an IC device is used as the electronic component to be tested will be representatively explained as “IC device 90”.

The tester 1 as the electronic component tester includes a handler 10 as an electronic component handler that transports the IC device 90 as the electronic component, a test unit 16, a reporting unit 40 including a display part 41 and a sound output part 45, an operation unit 42, and a control apparatus 30. Further, the tester 1 has a housing unit 5 including a cover housing the handler 10 and the test unit 16, and door parts 7 provided in the housing unit 5. Note that the housing unit 5 includes frames, wall parts, and covers. Further, the door parts 7 include push-pull doors, sliding doors, shutters, etc. which are capable of opening and closing between the inside the cover and the outside.

The handler 10 has a holding member that may hold the IC device 90 mounted thereon. The holding member has a recessed pocket and houses and holds the IC device 90 in the pocket. The holding member is also called a change kit and corresponds to e.g. a tray 200 used for a feed tray (not shown), a collection tray 19, or the like, a shuttle plate 100 (see FIGS. 4 and 5) used for an electronic component feed unit 14, an electronic component collection unit 18, a temperature control unit 12, and a rotary stage (not shown), or the like, etc.

Note that, as below, the feed tray (not shown), the collection tray 19, the electronic component feed unit 14, the electronic component collection unit 18, the temperature control unit 12, and the rotary stage (not shown) including the holding members are also referred to as “electronic component holding units” without distinction. Further, in FIG. 2, the shuttle plates 100 used for the electronic component feed unit 14, the electronic component collection unit 18, the temperature control unit 12, the rotary stage (not shown), etc. are omitted.

The shuttle plate 100 as the holding member shown in FIGS. 4 and 5 as one configuration example has recesses 111, 112, 113, 114, 115, 116, 117, 118 having bottoms recessed from an upper surface of abase material 101, that is, recessed from an upper surface 100a of the shuttle plate 100 as eight pockets housing the IC devices 90. The eight recesses 111 to 118 open upward, and have inclined surfaces 123 along which the cross-section areas gradually decrease from the upper surface 100a toward a lower surface 100b and have bottom portions 121 connecting to the inclined surfaces 123 via inner side surfaces 122 provided in the lower parts of the inclined surfaces 123. That is, each of the recesses 111 to 118 has the bottom portion 121, the four inner side surfaces 122 stood relative to the bottom portion 121, and the inclined surfaces 123 inclined from the inner side surfaces 122. The inclined surfaces 123 and the inner side surfaces 122 of the recesses 111 to 118 function as guide surfaces that guide the IC devices 90 into the recesses 111 to 118 when the IC devices 90 are mounted. Thereby, the IC devices 90 may be easily positioned and held in the shuttle plate 100. Note that the number of the recesses 111 to 118 as the pockets may be one or more as necessary.

Further, in the bottom portions 121 of the recesses 111 to 118, colored portions 140 colored by e.g. paint, ink, or reaction layers are provided on the entire surfaces of the bottom portions 121. It is preferable that the colored portions 140 are colored by a different color from the color of the upper surfaces of the IC devices 90 in a plan view from above of the IC devices 90 housed in the recesses 111 to 118. Further, it is preferable that the colored portions 140 are colored in a different color from the color of the upper surface 100a of the shuttle plate 100. In the embodiment, the upper surfaces of the IC devices 90 are black and the upper surface 100a of the shuttle plate 100 is a metallic color, and the bottom portions 121 are colored in red.

As described above, the bottom portions 121 of the recesses 111 to 118 are colored, and thereby, in an image captured by an imaging device 51 (see FIG. 3) as an imaging unit, which will be described later, the bottom portions 121 colored by the colored portions 140, the IC devices 90 housed in the recesses 111 to 118, and the upper surface 100a of the shuttle plate 100 are distinguished more clearly, and calculation accuracy of exposure areas of the bottom portions 121, which will be described later, may be improved.

The inner side surfaces 122 and the inclined surfaces 123 may be subjected to antireflection treatment for reduction of the reflection on the surfaces. Thereby, when the recesses 111 to 118 are imaged by the imaging device 51 as the imaging unit to be described later, entrance of unnecessary light into an image sensor (not shown) of the imaging device 51 may be suppressed. Accordingly, a more clear image may be obtained by the imaging device 51 to be described later. The antireflection treatment is not particularly limited to, but includes e.g. formation of an antireflection film, roughening treatment for increasing scattering of light, and blackening treatment for increasing absorption of light.

The sizes, shapes, arrangements of the recesses 111 to 118 are set to correspond to stored data including sizes, shapes, and arrangements of corresponding electronic components, in the embodiment, the IC devices 90. Specifically, center locations, numbers, arrangement pitches, contour dimensions, depths, etc. are set. Further, regarding the shuttle plate 100, the numbers of the arranged recesses 111 to 118 are set according to the respective configurations of the attached electronic component feed unit 14, electronic component collection unit 18, temperature control unit 12, and the rotary stage (not shown). The sizes of the recesses 111 to 118 are formed so that the contour shapes of the bottom portions 121 may be slightly larger than the contours of the IC devices 90. That is, the IC devices 90 are usually housed with slight clearances between the inner side surfaces 122 of the recesses 111 to 118 and themselves in contact with the bottom portions 121. As described above, the shuttle plate 100 is configured to have specifications corresponding to the respective configurations of the electronic component feed unit 14, the electronic component collection unit 18, the temperature control unit 12, and the rotary stage and the forms of the corresponding electronic components, and replaced and used according to the electronic components to be tested.

Note that the shuttle plate 100 exemplified in the embodiment has the eight recesses 111 to 118 arranged in two rows. Further, in the shuttle plate 100 of the embodiment, the configuration provided with the eight recesses 111 to 118 as the pockets is exemplified, however, any number of pockets may be provided.

Note that the tray 200 as the holding member has recesses (not shown) with bottoms as pockets housing the IC devices 90 like the above described shuttle plate 100. Regarding the recesses, like the above described shuttle plate 100, center locations, numbers, arrangement pitches, contour dimensions, depths, etc. are set according to the sizes and shapes of the IC devices 90. The tray 200 is replaced and used according to the electronic component to be tested like the above described shuttle plate 100.

As shown in FIG. 3, the handler 10 has an image acquisition unit 50 including the imaging device 51 as the imaging unit that can capture the image of the holding member including the shuttle plate 100 and the tray 200 and an illumination device 52. The image acquisition unit 50 is placed above the recesses 111 to 118 of the tray 200 or the shuttle plate 100. By the placement of the image acquisition unit 50, the bottom portions 121 of the recesses 111 to 118 and the IC devices 90 may be imaged in the plan view.

Note that the handler 10 of the embodiment holds as a configuration formed except the test unit 16 and a test control part 312 of the control apparatus 30, which will be described later, from the tester 1 shown in the block diagram of FIG. 6.

As shown in FIGS. 1 and 2, the tester 1 is divided into a tray feed region A1, a device feed region A2, a test region A3 in which the test unit 16 is placed, a device collection region A4, and a tray removal region A5.

These respective regions are partitioned from one another by wall parts, shutters, or the like (not shown). The device feed region A2 is a first chamber defined by the wall parts, shutters, or the like. The test region A3 is a second chamber defined by the wall parts, shutters, or the like. The device collection region A4 is a third chamber defined by the wall parts, shutters, or the like. The first chamber forming the device feed region A2, the second chamber forming the test region A3, and the third chamber forming the device collection region A4 are respectively configured to secure air-tightness and heat insulation properties. Thereby, the first chamber, the second chamber, and the third chamber may respectively maintain humidity and temperatures as constant as possible. Note that the interiors of the first chamber and the second chamber are respectively controlled at predetermined humidity and predetermined temperatures, and configured so that tests, for example, under a normal temperature environment, a lower temperature environment, and a higher temperature environment may be performed.

In the tester 1, the IC device 90 sequentially passes the respective regions from the tray feed region A1 to the tray removal region A5, and an electrical test is performed in the test region A3 in the middle. In the electrical test of the embodiment, for example, whether or not the IC device 90 is conducted is checked and whether or not expected output is obtained when a specific signal is input is checked. Thereby, whether or not the IC device 90 is disconnected or short-circuited may be judged. In addition, in the test unit 16, a test for checking operation of a circuit (not shown) of the IC device 90 or the like may be performed.

As below, referring to FIG. 2, the tester 1 will be explained sequentially from the tray feed region A1 to the tray removal region A5 with respect to each region.

### 1.1. Tray Feed Region

The tray feed region A1 is a region where the tray 200 as the holding member on which a plurality of untested IC devices 90 are arranged and held is fed as a feed tray. In the tray feed region A1, many of the trays 200 may be stacked.

### 1.2. Device Feed Region

The device feed region A2 is a region where the plurality of IC devices 90 on the tray 200 are respectively fed from the tray feed region A1 to the test region A3. Note that tray transport mechanisms 11A, 11B as transporters that transport the trays 200 are provided across the tray feed region A1 and the device feed region A2.

In the device feed region A2, the temperature control units 12 having the shuttle plates 100 as the holding members, a feed robot 13 as a transport robot, i.e., a transporter including a transport arm 131 (see FIG. 3), and a feed empty tray transport mechanism 15 are provided.

The temperature control unit 12 holds the IC devices 90 on the shuttle plate 100, performs control of heating or cooling the held IC devices 90, and adjusts the IC devices 90 to temperatures suitable for the test. In the configuration shown in FIG. 2, the two temperature control units 12 are arranged in the Y-axis directions and fixed. The IC devices 90 on the tray 200 transported in from the tray feed region A1 by the tray transport mechanism 11A are transported to one of the temperature control units 12 and held on the shuttle plate 100 provided in the temperature control unit 12.

The feed robot 13 as the transport robot is the transporter that transports the IC devices 90, and supported movably in the X directions, the Y directions, and the Z directions within the device feed region A2. The feed robot 13 serves to transport the IC devices 90 between the tray 200 transported in from the tray feed region A1 and the temperature control unit 12 and transport the IC devices 90 between the temperature control unit 12 and the electronic component feed unit 14, which will be described later. Note that the feed robot 13 has a plurality of gripping units (not shown) that grip the IC devices 90. The respective gripping units have suction nozzles and may grip the IC devices 90 by suction. Further, the feed robot 13 may adjust the IC devices 90 to the temperatures suitable for the test by heating or cooling the IC devices 90 like the temperature control unit 12.

The feed empty tray transport mechanism 15 is a transporter as a transport mechanism that transports the empty tray 200 after removal of all IC devices 90 in the X directions. After the transport, the empty tray 200 is returned from the device feed region A2 to the tray feed region A1 by the tray transport mechanism 11B.

### 1.3. Test Region

As shown in FIG. 2, the test region A3 is a region where the IC devices 90 are tested. In the test region A3, the electronic component feed units 14, the test unit 16, a measuring robot 17, and the electronic component collection units 18 are provided. Note that, in the embodiment, the electronic component feed units 14 and the electronic component collection units 18 are respectively configured to be independently movable, however, these may be coupled or integrally configured to be movable in the same direction.

The electronic component feed unit 14 is a transporter that holds the IC devices 90 controlled at a predetermined temperature in the shuttle plate 100 and transports the devices to the vicinity of the test unit 16. The electronic component feed units 14 can reciprocate along the X directions between the device feed region A2 and the test region A3. Further, in the configuration shown in FIG. 2, the two electronic component feed units 14 are arranged in the Y directions. The IC devices 90 on the temperature control unit 12 are transported to one of the electronic component feed units 14 and held. Note that the transport is performed by the feed robot 13. Further, in the electronic component feed units 14, the IC devices 90 may be adjusted to the temperatures suitable for the test by heating or cooling of the IC devices 90 like the temperature control units 12.

The measuring robot 17 is a transporter that transports the IC devices 90 and movably supported within the test region A3. The measuring robot 17 may transport the IC devices 90 on the electronic component feed unit 14 transported from the device feed region A2 onto the test unit 16 and mount the devices thereon. When the IC devices 90 are tested, the measuring robot 17 presses the IC devices 90 toward the test unit 16, and thereby, brings the IC devices 90 into contact with the test unit 16. Therefore, as will be described later, terminals of the IC devices 90 and probe pins of the test unit 16 are electrically coupled. Note that the measuring robot 17 has a plurality of gripping units (not shown) that grip the IC devices 90. The respective gripping units have suction nozzles and may grip the IC devices 90 by suction. Further, the measuring robot 17 may adjust the IC devices 90 to the temperatures suitable for the test by heating or cooling the IC devices 90 like the temperature control unit 12. In the embodiment, the single measuring robot 17 is provided as shown in the drawing, however, two or more of the measuring robots may be provided.

The electronic component collection unit 18 is a transporter that holds the IC devices 90 after the test in the test unit 16 and transports the devices to the device collection region A4. The electronic component collection units 18 can reciprocate along the X directions between the test region A3 and the device collection region A4. Further, in the configuration shown in FIG. 2, the two electronic component collection units 18 are arranged in the Y directions like the electronic component feed units 14. The IC devices 90 on the test unit 16 are transported to one of the electronic component collection units 18 and held. Note that the transport is performed by the measuring robot 17.

### 1.3.1. Test Unit

The test unit 16 is a unit that makes tests and examinations of electrical characteristics of the IC devices 90 and a holding unit that holds the IC devices 90 when testing the IC devices 90. A plurality of the probe pins electrically coupled to the terminals of the IC devices 90 with the IC devices 90 held are provided in the test unit 16. The terminals of the IC devices 90 and the probe pins are brought into electrical contact and coupled, and an electrical test of the IC device 90 is performed via the probe pins. Further, in the test unit 16, the IC devices 90 may be adjusted to the temperatures suitable for the test by heating or cooling of the IC devices 90 like the temperature control unit 12.

### 1.4. Device Collection Region

As shown in FIG. 2, the device collection region A4 is a region where the tested IC devices 90 are collected. In the device collection region A4, collection trays 19, a collection robot 20 as a transport robot, and collection empty tray transport mechanisms 21 are provided. Further, in the device collection region A4, three empty trays 200 are prepared.

The collection tray 19 is one of the electronic component holding units on which the IC devices 90 are held. The collection trays 19 are fixed within the device collection region A4 and three of the trays are arranged side by side in the X directions in this configuration. Further, the empty trays 200 are the electronic component holding units on which the IC devices 90 are mounted and three of the trays are arranged side by side in the X directions. The IC devices 90 on the electronic component collection unit 18 moved to the device collection region A4 are transported to one of these collection trays 19 and empty trays 200 and held. Thereby, the IC devices 90 are collected with respect to each test result and sorted. The sorting of the IC devices 90 based on the test results is performed by the collection robot 20. The collection robot 20 sorts the IC devices 90 according to a command by the control apparatus 30, which will be described later.

The collection robot 20 as the transport robot is a transporter that transports the IC devices 90, and supported movably in the X directions, the Y directions, and the Z directions within the device collection region A4. The collection robot 20 may transport the IC devices 90 from the electronic component collection unit 18 to the collection tray 19 or the empty tray 200. Note that the collection robot 20 has a plurality of gripping units (not shown) that grip the IC devices 90. The respective gripping units have suction nozzles and may grip the IC devices 90 by suction.

The collection empty tray transport mechanism 21 is a transporter as a transport mechanism that transports the empty tray 200 transported from the tray removal region A5 in the X directions. Then, after the transport, the empty tray 200 is placed in a location where the IC devices 90 are collected. That is, the empty tray 200 after transport may be one of the above described three empty trays 200.

### 1.5. Tray Removal Region

The tray removal region A5 is a region where the tray 200 on which the plurality of tested IC devices 90 are arranged is collected and removed. In the tray removal region A5, many of the trays 200 may be stacked. Note that tray transport mechanisms 22A, 22B that transport the trays 200 one by one are provided across the device collection region A4 and the tray removal region A5. The tray transport mechanism 22A transports the tray 200 with the tested IC devices 90 mounted thereon from the device collection region A4 to the tray removal region A5. The tray transport mechanism 22B transports the empty tray 200 for collection of the IC devices 90 from the tray removal region A5 to the device collection region A4.

In the first chamber, the second chamber, and the third chamber of the above described respective regions A1 to A5, temperature sensors that detect temperatures within the chambers, humidity sensors that detect relative humidity within the chambers, and oxygen concentration sensors that detect oxygen concentrations within the chambers (not shown) are respectively provided. Note that, in the embodiment, the temperature sensors, the humidity sensors, and the oxygen concentration sensors are provided in the respective chambers of the first chamber, the second chamber, and the third chamber, however, the temperature sensors, the humidity sensors, and the oxygen concentration sensors may be provided in any locations.

Further, the tester 1 has a dry air supply mechanism (not shown). The dry air supply mechanism is configured to supply a low-humidity gas including the air and nitrogen (hereinafter, also referred to as “dry air”) to the first chamber, the second chamber, and the third chamber. Accordingly, the dry air is supplied as necessary, and thereby, condensation and freezing of the IC devices 90 may be prevented.

Note that, in the above described embodiment, the tester 1 is configured to perform tests under a normal temperature environment, a lower temperature environment, and a higher temperature environment, however, may be configured to perform tests at least under one environment of the above described three environments. For example, the configurations for the lower temperature environment including the wall parts, shutters, hygrometers, oximeters, and dry air may not necessarily provided.

### 1.6. Control Apparatus

As shown in FIG. 6, the control apparatus 30 has a function of controlling the respective units of the tester 1 and includes a control unit 31 and a memory unit 32.

The control unit 31 includes e.g. a CPU (Central Processing Unit) and has a drive control part 311, the test control part 312, an imaging control part 313, an area data calculation part 314, a determination part 315, and a reporting processing part 316. The memory unit 32 includes e.g. a ROM (read only memory) and a RAM (Random Access Memory).

The control unit 31 has a function of displaying driving of the respective units, forming the tester 1, test results, image data, etc. on the display part 41, a function of performing processing according to input from the operation unit 42 executed by a user, etc.

Further, the control unit 31 performs imaging of the trays 200 and the shuttle plates 100 as holding members and determines presence or absence of the IC devices 90 housed in the recesses 111 to 118 of the trays 200 and the shuttle plates 100 or whether or not positions including displacement and tilts of the IC devices 90 are good. Specifically, the control unit 31 compares a reference area of the bottom portion 121 calculated from a preset plan view area of the IC device 90 and a plan view area of the bottom portion 121 colored by the colored portion 140 with a detection area of the bottom portion 121 detected from the image captured by giving an instruction to the imaging device 51, and determines presence or absence of the IC devices 90 housed in the recesses 111 to 118 or whether or not the positions of the IC devices 90 housed in the recesses 111 to 118 are good. Note that the determination and the determination method will be explained later in detail. Then, when making a determination as being abnormal in a determination result, the control unit 31 reports by sending a reporting signal to the reporting unit 40 or stops the operation of the tester 1 including the transport operation of the trays 200 and the shuttle plates 100. Note that the plan view refers to a view of an object in a location apart along a normal from the object when a line extending in a direction orthogonal to a contact plane on a surface of the object is the normal. Further, the plan view area refers to a surface area of the object in the plan view.

Note that the control unit 31 has a plurality of execution time patterns relating to execution times of the above described determination and may select the execution time of the determination from the plurality of execution time patterns. In this manner, the above described determination is performed at the execution time of the determination selected from the plurality of set execution time patterns, and thereby, the efficient determination may be made.

Further, as an example of the above described execution time of determination, the control unit 31 may set the execution time to an activation start time including reactivation after pausing of the handler 10 or the tester 1. In this manner, the above described determination is made at the activation start time including reactivation after pausing of the handler 10 or tester 1, and thereby, proper operation of the tester may be performed based on presence or absence of the IC devices 90 housed in the recesses 111 to 118 or whether or not the positions of the IC devices 90 housed in the recesses 111 to 118 are good.

Furthermore, as an example of the above described execution time of determination, the control unit 31 may set the execution time to a time when the door part 7 of the handler 10 or the tester 1 is closed in opening and closing operation, in other words, a time when the opened door part 7 is closed. In this manner, the above described determination is made based on the closing operation of the door part 7, and thereby, proper operation of the tester may be performed based on presence or absence of the IC devices 90 housed in the recesses 111 to 118 or whether or not the positions of the IC devices 90 housed in the recesses 111 to 118 are good after the user opens the door part 7 and performs some process.

The drive control part 311 controls driving etc. of the tray transport mechanisms 11A, 11B, the temperature control units 12, the feed robot 13, the feed empty tray transport mechanism 15, the electronic component feed units 14, the test unit 16, the measuring robot 17, the electronic component collection units 18, the collection robot 20, the collection empty tray transport mechanisms 21, and the tray transport mechanisms 22A, 22B.

The test control part 312 may perform e.g. tests as to whether or not electrical operations of the IC devices 90 placed in the test unit 16 are good or the like based on programs stored within the memory unit 32.

The imaging control part 313 controls driving etc. of the image acquisition unit 50 that performs imaging of the tray 200 or the shuttle plate 100 as the holding member. Further, the imaging control part 313 processes the signal from the imaging device 51, digitalizes the image of the tray 200 or the shuttle plate 100 acquired by the image acquisition unit 50, and generates image data.

The area data calculation part 314 acquires the preset plan view area of the IC device 90 and the plan view area of the bottom portion 121 colored by the colored portion 140 from the memory unit 32, and calculates the reference area as the exposure area of the bottom portion 121 from the acquired plan view area of the IC devices 90 and plan view area of the bottom portion 121. Note that the reference area includes the area of the bottom portion 121 exposed around the IC device 90 when the IC device 90 is held in the recesses 111 to 118 and the area of the bottom portion 121 exposed around the IC device 90 when the IC device 90 is not held in the recesses 111 to 118. Further, the plan view area of the IC devices 90 and the plan view area of the bottom portion 121 colored by the colored portion 140 may be set from an image captured by the imaging device 51 when the handler 10 is preliminarily operated and the IC devices 90 are transported onto the shuttle plate 100.

Furthermore, the area data calculation part 314 calculates e.g. a detection area as the plan view area of the bottom portion 121 exposed around the IC device 90 housed in the recesses 111 to 118 of the shuttle plate 100 based on two-dimensional image data formed by digitalization of the image of the recesses 111 to 118 in the tray 200 or the shuttle plate 100 captured by the image acquisition unit 50 using the imaging device 51.

The determination part 315 determines presence or absence of the IC devices 90 housed in the recesses 111 to 118 or whether or not the positions including displacement and tilts of the IC devices 90 housed in the recesses 111 to 118 are good based on the reference area of the bottom portion 121 and the detection area as the plan view area of the bottom portion 121 exposed around the IC device 90 calculated by the area data calculation part 314. Note that, in the comparison between the reference area of the bottom portion 121 and the detection area of the bottom portion 121, the determination part 315 may apply a method of comparing the respective areas and making a determination based on whether or not the difference thereof is within a predetermined range or a method of obtaining a ratio of the detection area of the bottom portion 121 to the reference area of the bottom portion 121 and making a determination based on whether or not the ratio is within a predetermined range. The determination part 315 determines the presence or absence of the IC devices 90 or whether or not the positions including displacement and tilts of the IC devices 90 are good by comparison between e.g. the reference area of the bottom portion 121 and the detection area of the bottom portion 121.

The specific determination method on the above described determination by the determination part 315 will be explained later in detail. The determination by the determination part 315 may be similarly applied and executed in the tray 200.

Note that the determination part 315 may select the recesses 111 to 118 as an object of determination in the determination as to the presence or absence of the IC devices 90 or whether or not the positions including displacement and tilts of the IC devices 90 are good. Specifically, the determination part 315 may select the object of determination for the determination as to the presence or absence of the IC devices 90 or whether or not the positions including displacement and tilts of the IC devices 90 are good to be all of the recesses 111 to 118 or one of the recesses, e.g. one recess 111. The determination location is selected, and thereby, the determination may be made efficient. Note that, for the selection of the determination location, a checkbox of a selection window (not shown) displayed on the display part 41 or the like may be used. Further, the above described selection of the determination location may be similarly applied to the tray 200.

When the presence or absence of the IC devices 90 in the recesses 111 to 118 or whether or not the positions including displacement and tilts of the IC devices 90 housed in the recesses 111 to 118 are good is determined as being abnormal in the determination by the determination part 315, the reporting processing part 316 generates reporting information based on the determination result and transmits the generated reporting information to the reporting unit 40.

The memory unit 32 stores programs, data, etc. for various kinds of processing by the control unit 31. Further, the memory unit 32 stores the stored data of the sizes, shapes, and arrangements of the corresponding electronic components, in the embodiment, the IC devices 90 and arrangement data of the recesses 111 to 118 based thereon as setup recipes. Furthermore, the memory unit 32 stores the plan view area of the set IC device 90 and the plan view area of the bottom portion 121 colored by the colored portion 140 in the set recesses 111 to 118. In addition, the memory unit 32 stores threshold values for determinations set as determination criteria in the determination part 315.

The plan view area of the IC device 90 and the plan view area of the bottom portion 121 colored by the colored portion 140 in the recesses 111 to 118 stored in the memory unit 32 may be set using preset data or input by the user using the operation unit 42 or the like. Further, the plan view area of the IC device 90 and the plan view area of the bottom portion 121 colored by the colored portion 140 in the recesses 111 to 118 may be set from an image captured by the imaging device 51 when the handler 10 is preliminarily operated.

### 1.7. Reporting Unit

As shown in FIGS. 1 and 6, the reporting unit 40 has the display part 41 that can display images, the sound output part 45 that can output voice, beep sound, etc. The reporting unit 40 may issue reporting information on the determination result generated by the reporting processing part 316 as e.g. warning display using images of characters and illustrations in the display part 41 or output of voice and warning sound in the sound output part 45.

The display part 41 displays driving statuses of the respective units and test results or determination results as to the presence or absence of the IC devices 90 or whether or not the positions are good in the tray 200 or the shuttle plate 100. The display part 41 may include e.g. a liquid crystal display panel, a display panel of organic EL, or the like. The user may set various kinds of processing and conditions of the tester 1 and confirm results via the display part 41. Additionally, the user may confirm the reporting information of the determination results as to the presence or absence of the IC devices 90 or whether or not the positions are good in the tray 200 or the shuttle plate 100 by image display of characters and illustrations.

The sound output part 45 includes a speaker (not shown) or the like and may output and report the information of the determination results as to the presence or absence of the IC devices 90 or whether or not the positions are good in the tray 200 or the shuttle plate 100 as sound information including voice and beep sound.

### 1.8. Operation Unit

The operation unit 42 is an input device including a keyboard and a mouse, and outputs an operation signal according to the operation by the user to the control unit 31. Therefore, the user may give instructions of various kinds of processing etc. to the control unit 31 using the keyboard and the mouse. Note that, in the embodiment, the keyboard and the mouse are used as the operation unit 42, however, the operation unit 42 is not limited to those, but may be e.g. an input device including a trackball and a touch panel.

### 1.9. Image Acquisition Unit

The image acquisition unit 50 has a function of acquiring the images of the trays 200 or the shuttle plates 100 placed in the electronic component holding units and the recesses 111 to 118. As shown in FIG. 2, the image acquisition units 50 are provided in the feed robot 13 and the collection robot 20 as the transport robots in the device feed region A2 and the device collection region A4. That is, the image acquisition unit 50 is provided in a location where the unit can acquire the images of the trays 200 and the shuttle plates 100 placed in the electronic component holding units.

Specifically, as shown in FIG. 3, the image acquisition units 50 are attached to the transport arms 131 of the feed robot 13 and the collection robot 20. The image acquisition units 50 are provided above the electronic component holding units. Note that, in the embodiment, when the respective feed robot 13 and collection robot 20 are regarded as the single image acquisition units 50, the number of image acquisition units 50 is two, however, any number of image acquisition units 50 may be provided.

The image acquisition units 50 are supported by the feed robot 13 and the collection robot 20 to be placed above the recesses 111 to 118 of the trays 200 or the shuttle plates 100 placed in the electronic component holding units. Thereby, the image acquisition unit 50 may image the recesses 111 to 118 in the plan view and improve shape accuracy of the captured image.

The image acquisition unit 50 has the imaging device 51 as the imaging unit and the illumination device 52. Note that the illumination device 52 may continuously illuminate or intermittently emit strong light (flash) as long as the device may control the exposure time.

The imaging device 51 as the imaging unit has an image sensor that receives light reflected by the tray 200 or the shuttle plates 100 placed in the electronic component holding unit or the IC devices 90 and converts the light into an electrical signal. The imaging device 51 is not particularly limited to, but includes e.g. a camera using a CCD (Charge Coupled Device) image sensor as the image sensor and an electronic camera (digital camera) using a CMOS (Complementary Metal Oxide Semiconductor) image sensor as the image sensor. The image data is analyzed using e.g. differential interferometry, Fourier transform, or the like, and thereby, microscopic shapes and shapes hard to be seen can be emphasized and detection sensitivity of the shapes can be improved. Further, microscopic scratches and scratches hard to be seen can be emphasized and detection sensitivity of the scratches can be improved.

The imaging device 51 is configured to have an imaging area in a size substantially equal to the size of the recesses 111 to 118 provided in the tray 200 or the shuttle plate 100 to a size substantially equal to or larger than the size of the tray 200 or the shuttle plate 100.

It is preferable that the imaging device 51 includes an optical system such as an optical lens or autofocus mechanism (not shown). Thereby, for example, even when the heights (heights in the Z directions) of the tray 200 and the shuttle plate 100 relative to the imaging device 51 vary, clear images may be obtained.

The illumination device 52 is a light source driven at imaging of the tray 200 or the shuttle plate 100 by the imaging device 51 and irradiating the tray 200 or the shuttle plate 100 with light. By the illumination device 52, darkness of the image due to insufficient illumination may be suppressed and the clearer image may be obtained.

In the embodiment, the illumination device 52 has an annular shape and is placed around the imaging device 51. Thereby, the tray 200 or the shuttle plate 100 may be uniformly irradiated with light. Note that the shape and the placement of the illumination device 52 are not limited to those of the above described configuration.

The image acquisition unit 50 having the above described configuration irradiates the tray 200 or the shuttle plate 100 placed in the electronic component holding unit and the IC devices 90 with light by the illumination device 52, and images the recesses 111 to 118 of the tray 200 or the shuttle plate 100 and the IC devices 90 by the imaging device 51. The signal from the imaging device 51 is taken into the imaging control part 313 of the above described control unit 31. The imaging control part 313 processes the signal from the imaging device 51, and generates the images of the recesses 111 to 118 of the tray 200 or the shuttle plate 100 and the IC devices 90 as two-dimensional image data.

### 2. Determination Method by Control Unit

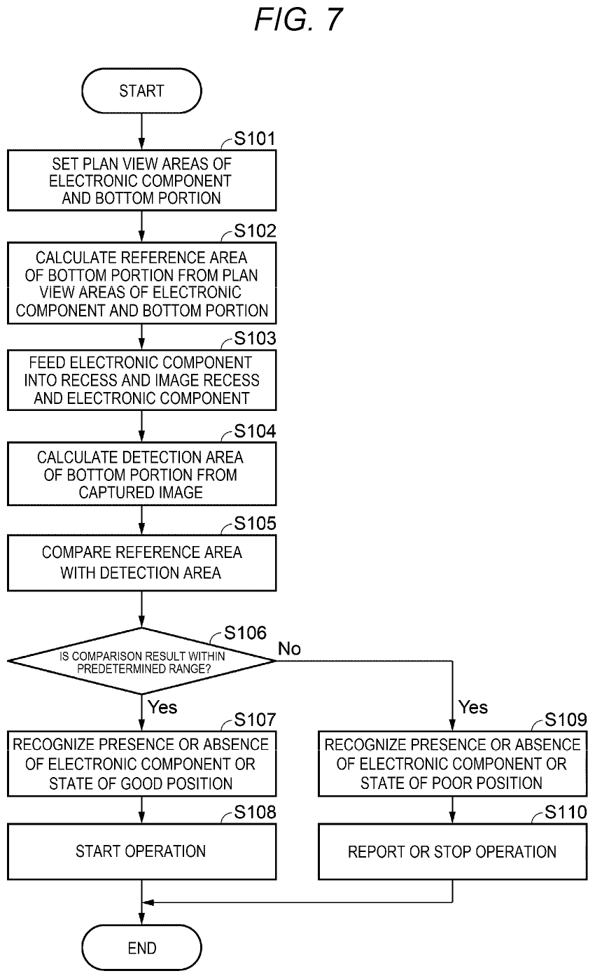

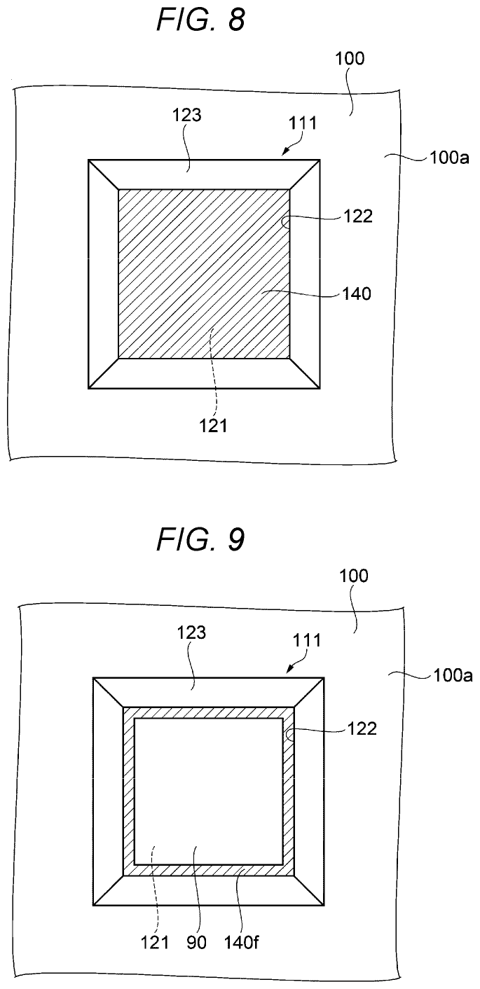

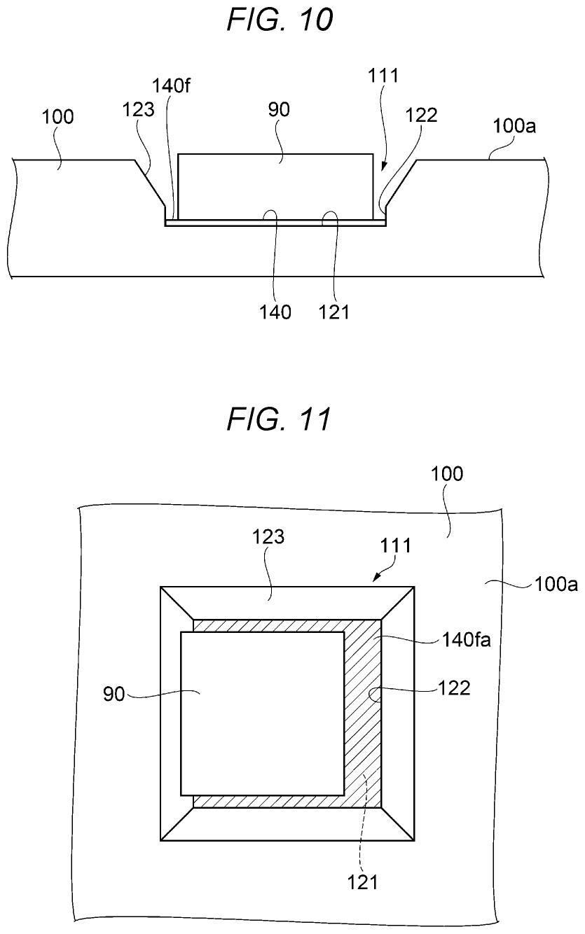

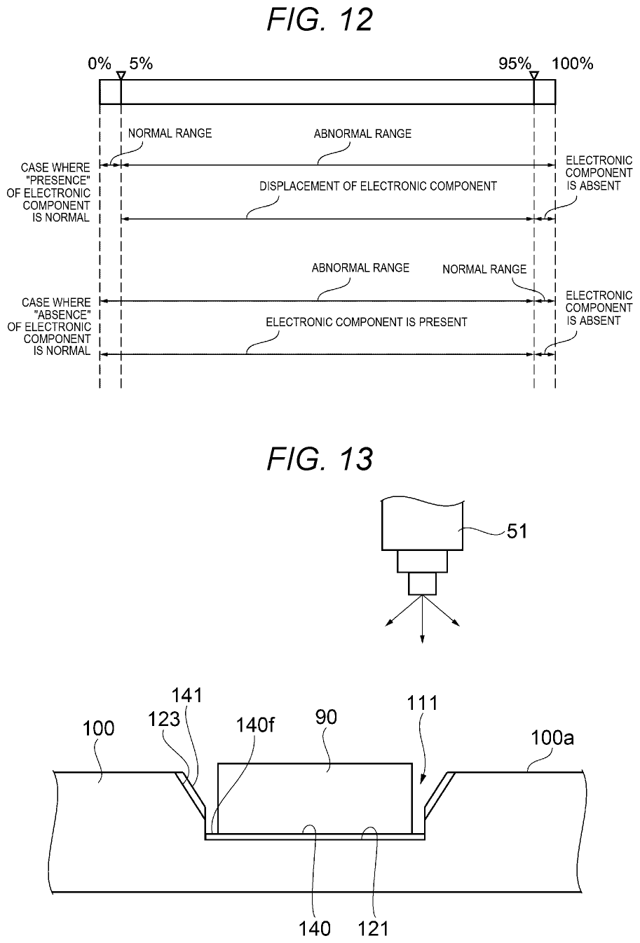

As below, a series of operation of the electronic handler having the above described configuration and the electronic component tester using the electronic handler will be explained, and a method of determining the presence or absence of the IC devices 90 or whether or not the positions including displacement and tilts of the IC devices 90 are good by the control unit 31 will be explained with reference to FIGS. 7, 8, 9, 10, 11, and 12. FIG. 7 is the flowchart showing the checking method of the IC device as the electronic component housed in the recess. FIG. 8 is the enlarged plan view showing the recess of the shuttle plate. FIG. 9 is the enlarged plan view showing the recess of the shuttle plate with the IC device housed therein. FIG. 10 is the enlarged sectional view showing the recess of the shuttle plate with the IC device housed therein. FIG. 11 is the plan view showing the case where the housing location of the IC device is displaced. FIG. 12 is the explanatory chart relating to the determination of the position or presence or absence of the IC device. Note that the respective elements forming the handler 10 as the above described electronic component handler and the tester 1 as the electronic component tester will be explained using the same signs. Further, as below, the recess 111 will be explained as a representative example of the recesses 111 to 118, and the same applies to the other recesses 112 to 118.

First, prior to the activation of the tester 1, the user sets the plan view area of the IC device 90 to be transported as the electronic component of the test object and, as shown in FIG. 8, sets the plan view area of the bottom portion 121 colored by the colored portion 140 in the recess 111 recessed from the upper surface 100a of the shuttle plate 100 (step S101). Note that the recess 111 has the bottom portion 121, the inner side surfaces 122 stood from the bottom portion 121, and the inclined surfaces 123 inclined from the inner side surfaces 122 to the upper surface 100a. Further, the plan view area of the IC device 90 and the plan view area of the bottom portion 121 may be set by reading from the setup recipe stored in the memory unit 32 or input by the user using the operation unit 42 or the like.

The control unit 31 may calculate the plan view area of the IC device 90 and the plan view area of the bottom portion 121 by preliminary operation of the handler 10 based on the captured image. In this manner, the plan view area of the IC device 90 and the plan view area of the bottom portion 121 are obtained based on the images by direct imaging of the recess 111 of the shuttle plate 100 and the IC device 90 housed in the recess 111, and thereby, the plan view areas according to the actual state may be obtained.

Then, the area data calculation part 314 of the control unit 31 calculates the reference area of the bottom portion 121 as an area of a colored portion 140f exposed around the IC device 90 when the IC device 90 is housed in the recess 111 as shown in FIGS. 9 and 10 from the plan view area of the set IC device 90 and the plan view area of the colored bottom portion 121 (step S102).

Note that the reference area of the bottom portion 121 may be calculated based on the plan view area of the IC device 90 and the colored portion 140 set from the image of the IC device 90 transported to the shuttle plate 100 by preliminary operation of the handler 10 and captured by the imaging device 51. Here, in other words, the reference area is an area set as a reference value of the colored portion 140f exposed as seen from above between the outer edge of the IC device 90 and the inner side surfaces 122 of the recess 111.

Then, the control unit 31 activates the handler 10 and images the transported shuttle plate 100 and the IC device 90 by the imaging device 51. In other words, the unit images the recess 111 of the shuttle plate 100 and the IC device 90 housed in the recess 111 by the imaging device 51, and acquires the images of those (step S103). The captured images contain the bottom portion 121 without the IC device 90 housed therein, i.e., the image of the entire colored portion 140 and the bottom portion 121 with the IC device 90 housed therein, i.e., the bottom portion 121 exposed around the IC device 90.

Then, the area data calculation part 314 of the control unit 31 calculates the detection area detected based on the images captured at step S103 (step S104). Note that the detection area calculated here is the real area of the colored portion 140f exposed as seen from above between the outer edge of the IC device 90 and the inner side surfaces 122 of the recess 111, in the position of the IC device 90 actually housed in the recess 111.

Then, the determination part 315 of the control unit 31 compares the reference area of the bottom portion 121 of the recess 111 applied to the IC device 90 moving as the test object with the detection area of the bottom portion 121 detected from the images captured by the imaging device 51 according to an instruction (step S105).

Then, the determination part 315 determines whether or not the comparison result between the reference area of the bottom portion 121 and the detection area of the bottom portion 121 is within a set predetermined range (step S106). At step S106, when the comparison result between the reference area of the bottom portion 121 and the detection area of the bottom portion 121 is within the set predetermined range (step S106: Yes), the determination part 315 determines a state of “good” as to the housing of the IC device 90 in the recess 111 or the position of the IC device 90 housed in the recess 111 (step S107).

Specifically, the determination at step S106: Yes shows a state in which the IC device 90 is housed in the recess 111 when the housing of the IC device 90 in the recess 111 is set to “presence”, or a state in which the IC device 90 is not housed in the recess 111 when the housing of the IC device 90 in the recess 111 is set to “absence”. Or, the determination at step S106: Yes shows a state in which no displacement or tilt is produced in the position of the IC device 90 housed in the recess 111 (see FIG. 9).

Note that, in the determination by the comparison between the reference area of the bottom portion 121 and the detection area of the bottom portion 121 at step S106, there are a method of simply comparing the respective areas and making a determination based on whether or not the difference thereof is within the predetermined range and a method of obtaining a ratio of the detection area of the bottom portion 121 to the reference area of the bottom portion 121 and making a determination based on whether or not the ratio is within the predetermined range, and either one may be used.

Here, in the method of obtaining the ratio of the detection area of the bottom portion 121 to the reference area of the bottom portion 121 and making the determination based on whether or not the ratio is within the predetermined range, a reference ratio of the bottom portion 121 calculated from the plan view area of the set IC device 90 and the plan view area of the bottom portion 121 and a detection ratio of the bottom portion 121 detected from the images captured by the imaging device 51 are compared, and a determination is made based on whether or not the ratio thereof is within the predetermined range.

Further, as shown in FIG. 12, in the determination at step S106, the determination is made with distinction between the case were “presence” of the IC device 90 as the electronic component is set, i.e., the case where “presence” of the IC device 90 is normal and the case were “absence” of the IC device 90 as the electronic component is set, i.e., the case where “absence” of the IC device 90 is normal. Note that, in FIG. 12, of the above described two determination methods, the latter method of obtaining the ratio of the detection area of the bottom portion 121 to the reference area of the bottom portion 121 and making the determination based on whether or not the ratio is within the predetermined range is exemplified.

First, the case where “presence” of the IC device 90 is normal shown in the upper part of FIG. 12 is explained. In this example, regarding the ratio of the detection area to the reference area of the bottom portion 121, “5%” is set as a threshold value for distinction between normal and abnormal. When the ratio of the detection area is equal to or smaller than 5%, that is, when the difference between the detection area and the reference area is smaller, a determination as being normal is made. In this example, for instance, when the ratio of the detection area is equal to or smaller than 5%, a determination that the displacement and tilt of the housed IC device 90 are within a normal range is made and, when the ratio is larger than 5%, a determination that the displacement and tilt of the housed IC device 90 are within an abnormal range is made. Or, when the ratio of the detection area is larger than 95%, a determination that the IC device 90 is not housed is made, not the determination that the displacement and tilt of the housed IC device 90 are abnormal.

Next, the case where “absence” of the IC device 90 is normal shown in the lower part of FIG. 12 is explained. In this example, regarding the ratio of the detection area to the reference area of the bottom portion 121, “95%” is set as a threshold value for distinction between normal and abnormal. When the ratio of the detection area is larger than 95%, that is, when the difference between the detection area and the reference area is larger, a determination as being normal is made. In this example, for instance, when the ratio of the detection area is larger than 95%, a normal state in which the IC device 90 is not housed is determined and, when the ratio is equal to or smaller than 95%, the so-called abnormal state in which the IC device 90 that is not supposed to be housed is housed is determined.

Then, when confirming the state of “good” at step S107, the control unit 31 starts operation of the tester 1 including the transport operation of the trays 200 and the shuttle plates 100 (step S108).

Or, at step S106, when the comparison result between the reference area of the bottom portion 121 and the detection area of the bottom portion 121 is not within the set predetermined range (step S106: No), the determination part 315 determines a state of “poor” of the housing of the IC device 90 in the recess 111 or the position of the IC device 90 housed in the recess 111 (step S109).

Specifically, the determination at step S106: No shows a state in which the IC device 90 is not housed in the recess 111 when the housing of the IC device 90 in the recess 111 is set to “presence”, or a state in which the IC device 90 is housed in the recess 111 when the housing of the IC device 90 in the recess 111 is set to “absence”. Or, the determination at step S106: No shows a state in which displacement or tilt is produced in the position of the IC device 90 housed in the recess 111 (see FIG. 11).

Note that the IC device 90 in the state shown in FIG. 11 is housed with displacement toward the inclined surface 123 side from the side surface 122 of the recess 111. The state shows that a part of the device runs on the inclined surface 123 and the device partially floats from the bottom portion 121, that is, the device tilts as seen from the section direction. In this regard, the area of a colored portion 140fa exposed around the IC device 90 including the opposite side to the inclined surface 123 at which the IC device 90 is displaced is larger.

Then, when confirming the state of “poor” at step S109, when the determination of the presence or absence, the position, or the like of the IC device 90 is abnormal is made, the control unit 31 generates reporting information for reporting the abnormality based on the determination result, and reports the generated reporting information from the reporting unit 40 or stops the operation of the tester 1 including the transport operation of the trays 200 and the shuttle plates 100 (step S110).

Through the above described steps, a series of procedures of the method of determining the presence or absence of the IC devices 90 or whether or not the positions including displacement and tilts of the IC devices 90 are good by the control unit 31 of the tester 1 ends.

According to the handler 10 and the tester 1 using the handler 10 having the above described configurations, the following effects may be exerted. The handler 10 and the tester 1 using the handler 10 may sense slight exposure of the bottom portions 121 because the bottom portions 121 of the recesses 111 to 118 are colored by the colored portions 140, and the differences between the colored bottom portions 121 and the IC devices 90 as the electronic components housed in the recesses 111 to 118, the upper surface 100a of the shuttle plate 100, etc. are clearer in the images captured by the imaging units 51. Therefore, the handler 10 and the tester 1 using the handler 10 compare the reference areas of the bottom portions 121 with the detection areas of the bottom portions 121 or obtain the ratios of the detection areas of the bottom portions 121 to the reference areas of the bottom portions 121 and determine whether or not the ratios are within the predetermined range in the images captured by the imaging devices 51, and thereby, may determine the presence or absence of the IC devices 90 housed in the recesses 111 to 118 or whether or not the positions of the IC devices 90 housed in the recesses 111 to 118 are good. Therefore, compared to the method of image matching of comparing test image data with reference image data of related art, shape recognition or comparison between the recognized shape image and the reference image is unnecessary, and thus, in the handler 10 and the tester 1 using the handler 10, the time taken for the determination as to the presence or absence of the IC devices 90 housed in the recesses 111 to 118 or whether or not the positions of the IC devices 90 housed in the recesses 111 to 118 are good may be made shorter.

Further, when an abnormality is determined in the above described determinations, the handler 10 and the tester 1 using the handler 10 generate the reporting information for reporting the abnormality based on the determination result, and report the generated reporting information from the reporting unit 40 or stop the operation of the tester 1 including the transport operation of the trays 200 and the shuttle plates 100. Thereby, when the determination that the IC devices 90 are not housed in the recesses 111 to 118 or the positions of the IC devices 90 housed in the recesses 111 to 118 are skewed is made, the user may properly perceive that and malfunction of the handler 10 and the tester 1 using the handler 10 may be suppressed.

Note that, in the above described embodiment, the configuration in which the colored portions 140 are provided on the bottom portions 121 of the recesses 111 to 118 provided in the shuttle plate 100 as the holding member is explained as an example. In addition, as shown in FIG. 13, inclined surface colored portions 141 may be provided on the inclined surfaces 123. It is preferable that the inclined surface colored portions 141 provided on the inclined surfaces 123 are formed in a different color from that of the bottom portions 121. That is, it is preferable that the color of the bottom portions 121 and the color of the inclined surfaces 123 are made different. According to the configuration, even when imaging of the bottom portions 121 of the recesses 111 to 118 behind the IC devices 90 is difficult due to a viewing angle formed according to a location relationship between the placement location of the imaging unit 51 and the part to be imaged, the areas of the inclined surfaces 123 colored in the different color by the inclined surface colored portions 141 are used, and thereby, whether or not the positions of the IC devices 90 are good may be determined. Note that FIG. 13 is the sectional view showing the configuration example in which inclined surfaces of the recess are colored.

The imaging device 51 as the imaging unit may perform imaging with respect to each of the plurality of recesses 111 to 118 in advance and acquire the plan view areas of the IC devices 90 and the plan view areas of the bottom portions 121 with respect to each of the recesses 111 to 118. Specifically, the imaging device 51 may have a movable unit (not shown) that may vary the imaging direction or a moving unit (not shown) that can move the imaging device 51 may be provided. As described above, the imaging device 51 performs imaging with respect to each of the recesses 111 to 118, and thereby, the reference areas based on different images with respect to each of the recesses 111 to 118 may be acquired to address tilt differences in the optical axis of the imaging device 51 depending on the respective locations of the plurality of recesses 111 to 118, in other words, changes of images due to differences of viewing angles.

Further, a plurality of the imaging devices 51 as imaging units may be placed. For example, the plurality of imaging devices 51 assigned to the plurality of recesses 111 to 118 may be provided. The plurality of imaging devices are provided, and thereby, the viewing angles of the imaging devices 51 may be made smaller and accuracy of the captured images may be made higher.

As below, the details derived from the above described embodiments will be described as respective embodiments.

### Embodiment 1

An electronic component handler according to the embodiment is an electronic component handler that transports an electronic component to a test unit, including a holding member including a recess having a colored bottom portion and housing the electronic component in the recess, an imaging unit that images the recess, and a control unit that compares a reference area of the bottom portion previously calculated from a plan view area of the electronic component and a plan view area of the bottom portion with a detection area of the bottom portion detected from an image captured by the imaging unit, and determines presence or absence of the electronic component housed in the recess or whether or not a position of the electronic component housed in the recess is good.

According to the embodiment, the bottom portion of the recess is colored, and thereby, in the captured image, the difference between the bottom portion and another part such as the electronic component housed in the recess is clearer. Accordingly, even the colored portion slightly exposed around the electronic component may be sensed, and the presence or absence of the electronic component housed in the recess or whether or not the position of the electronic component housed in the recess is good may be determined by comparison between the reference area of the bottom portion and the detection area of the bottom portion. Therefore, compared to the method of image matching of comparing test image data with reference image data, shape recognition or comparison between the recognized shape image and the reference image is unnecessary, and thus, the time taken for the determination may be made shorter.

### Embodiment 2

In the electronic component handler according to the embodiment, a color coloring the bottom portion may be different from a color of the electronic component.

According to the embodiment, in the captured image, distinction between the bottom portion and the electronic component housed in the recess is clearer, and calculation accuracy of the area of the bottom portion slightly exposed around the electronic component may be improved.

### Embodiment 3

In the electronic component handler according to the embodiment, a color coloring the bottom portion may be different from a color of the holding member.

According to the embodiment, distinction between the bottom portion and the holding member around the recess is clearer and calculation accuracy of the exposure area of the bottom portion may be improved.

### Embodiment 4

In the electronic component handler according to the embodiment, the imaging unit may be placed above the recess.

According to the embodiment, the bottom portion and the electronic component may be imaged in the plan view and shape accuracy of the captured image may be improved.

### Embodiment 5

In the electronic component handler according to the embodiment, the control unit may acquire the plan view area of the electronic component and the plan view area of the bottom portion from an image previously captured by the imaging unit.

According to the embodiment, the plan view area of the electronic component and the plan view area of the bottom portion are obtained based on the images by direct imaging of the recess of the holding member and the electronic component housed in the recess, and thereby, the plan view area of the electronic component and the plan view area of the bottom portion according to an actual state may be obtained.

### Embodiment 6

In the electronic component handler according to the embodiment, a plurality of the recesses may be provided, the imaging unit may previously image with respect to each of the recesses, and the control unit may acquire the plan view area of the electronic component and the plan view area of the bottom portion in correspondence with the captured images of the respective recesses.

According to the embodiment, the reference areas based on different images with respect to each of the recesses may be acquired to address tilt differences in the optical axis of the imaging unit depending on the respective locations of the plurality of recesses, in other words, changes of images due to differences of viewing angles.

### Embodiment 7

In the electronic component handler according to the embodiment, the image previously captured by the imaging unit may include an image of the bottom portion in which the electronic component is not housed and an image of the bottom portion in which the electronic component is housed.

According to the embodiment, the reference image of the bottom portion and the detection area of the bottom portion may be calculated from the image of the bottom portion in which the electronic component is not housed and the image of the bottom portion in which the electronic component is housed.

### Embodiment 8

In the electronic component handler according to the embodiment, the holding member may include an inclined surface connecting to the bottom portion, and the inclined surface may be colored in a different color from that of the bottom portion.

According to the embodiment, when imaging of the bottom portion of the recess behind the electronic component is difficult due to a viewing angle, the area of the inclined surface colored in the different color is used, and thereby, whether or not the position of the electronic component is good may be determined.

### Embodiment 9

In the electronic component handler according to the embodiment, a reporting unit is provided, wherein the control unit may transmit a signal to the reporting unit when determining that the electronic component is not housed in the recess or when determining that a position of the electronic component housed in the recess is skewed, and the reporting unit may receive the signal and report.

According to the embodiment, the user may properly perceive when the determination that the electronic component is not housed in the recess or the position of the electronic component housed in the recess is skewed is made.

### Embodiment 10

In the electronic component handler according to the embodiment, the control unit may stop the transport when determining that the electronic component is not housed in the recess or when determining that a position of the electronic component housed in the recess is skewed.

According to the embodiment, malfunction may be suppressed when the determination that the electronic component is not housed in the recess or the position of the electronic component housed in the recess is skewed is made.

### Embodiment 11

An electronic component handler according to the embodiment is an electronic component handler that transports an electronic component to a test unit, including a holding member including a recess having a colored bottom portion and housing the electronic component in the recess, an imaging unit that images the recess, and a control unit that compares a reference ratio of the bottom portion previously calculated from a plan view area of the electronic component and a plan view area of the bottom portion with a detection ratio of the bottom portion detected from an image captured by the imaging unit, and determines presence or absence of the electronic component housed in the recess or whether or not a position of the electronic component housed in the recess is good.

According to the embodiment, the bottom portion of the recess is colored, and thereby, in the captured image, the difference between the bottom portion and another part such as the electronic component housed in the recess is clearer and slight exposure may be sensed. The presence or absence of the electronic component housed in the recess or whether or not the position of the electronic component housed in the recess is good may be determined by comparison between the reference ratio of the bottom portion and the detection ratio of the bottom portion. Therefore, compared to the method of image matching of comparing test image data with reference image data, shape recognition or comparison between the recognized shape image and the reference image is unnecessary, and thus, the determination in the shorter time may be performed.

### Embodiment 12

An electronic component tester according to the embodiment includes one of the electronic component handlers according to Embodiment 1 to Embodiment 11 and a test unit that tests the electronic component transported by the electronic component handler.

According to the embodiment, in the electronic component tester, the bottom portion of the recess is colored, and thereby, slight exposure may be sensed, and the presence or absence of the electronic component housed in the recess or whether or not the position of the electronic component housed in the recess is good may be determined. Therefore, compared to the method of image matching of comparing test image data with reference image data, shape recognition or comparison between the recognized shape image and the reference image is unnecessary, and thus, the determination in the shorter time may be performed.

What is claimed is:

1. An electronic component handler that transports an electronic component to a test unit, comprising:
a holding member including a recess having a colored bottom portion and housing the electronic component in the recess;
an imaging unit that images the recess; and
a control unit that:
compares a reference area of the bottom portion with a detection area of the bottom portion,
the reference area of the bottom portion is previously calculated from a plan view area of the electronic component and a plan view area of the bottom portion,
the detection area of the bottom portion is detected from an image captured by the imaging unit, and
determines presence or absence of the electronic component housed in the recess or whether or not a position of the electronic component housed in the recess is good.

2. The electronic component handler according to claim 1, wherein
a color coloring the bottom portion is different from a color of the electronic component.

3. The electronic component handler according to claim 1, wherein
a color coloring the bottom portion is different from a color of the holding member.

4. The electronic component handler according to claim 1, wherein
the imaging unit is placed above the recess.

5. The electronic component handler according to claim 1, wherein
the control unit acquires the plan view area of the electronic component and the plan view area of the bottom portion from an image previously captured by the imaging unit.

6. The electronic component handler according to claim 5, wherein
a plurality of the recesses are provided,
the imaging unit previously images with respect to each of the recesses, and
the control unit acquires the plan view area of the electronic component and the plan view area of the bottom portion in correspondence with the captured images of the respective recesses.

7. The electronic component handler according to claim 5, wherein
the image previously captured by the imaging unit includes an image of the bottom portion in which the electronic component is not housed and an image of the bottom portion in which the electronic component is housed.

8. The electronic component handler according to claim 1, wherein
the holding member includes an inclined surface connecting to the bottom portion, and
the inclined surface is colored in a different color from that of the bottom portion.

9. The electronic component handler according to claim 1, further comprising a reporting unit, wherein
the control unit transmits a signal to the reporting unit when determining that the electronic component is not housed in the recess or when determining that a position of the electronic component housed in the recess is skewed, and
the reporting unit receives the signal and reports.

10. The electronic component handler according to claim 1, wherein
the control unit stops the transport when determining that the electronic component is not housed in the recess or when determining that a position of the electronic component housed in the recess is skewed.

11. An electronic component tester comprising:
the electronic component handler according to claim 1; and
a test unit that tests an electronic component transported by the electronic component handler.

12. An electronic component handler that transports an electronic component to a test unit, comprising:
a holding member including a recess having a colored bottom portion and housing the electronic component in the recess;
an imaging unit that images the recess; and
a control unit that:
compares a reference ratio of the bottom portion with a detection ratio of the bottom portion,
the reference ratio of the bottom portion is previously calculated from a plan view area of the electronic component and a plan view area of the bottom portion,
the detection ratio of the bottom portion is detected from an image captured by the imaging unit, and
determines presence or absence of the electronic component housed in the recess or whether or not a position of the electronic component housed in the recess is good.

13. An electronic component tester comprising:
the electronic component handler according to claim 12; and
a test unit that tests an electronic component transported by the electronic component handler.
